(19) United States
(12) Patent Application Publication
(10) Pub. No.: US 2026/0150678 A1
(43) Pub. Date: May 28, 2026

(54) SEMICONDUCTOR DEVICE AND VEHICLE

(71) Applicant: FUJI ELECTRIC CO., LTD., Kawasaki-shi (JP)

(72) Inventor: Tomohiro ISONO, Kawasaki-shi (JP)

(73) Assignee: FUJI ELECTRIC CO., LTD., Kawasaki-shi (JP)

(21) Appl. No.: 19/312,256

(22) Filed: Aug. 27, 2025

(30) Foreign Application Priority Data
Nov. 28, 2024 (JP) 2024-206883

(51) Int. Cl. H01L 23/00; B60R 16/02; H01L 23/049; H01L 23/373; H01L 23/473

(52) U.S. Cl. CPC H10W 40/255; H10W 40/47; H10W 76/136; B60R 16/02; H10W 72/634; H10W 72/871; H10W 72/884; H10W 72/886; H10W 90/734; H10W 90/755; H10W 90/767

(57) ABSTRACT

A semiconductor device, including: a semiconductor element that has, formed at a first surface thereof: a pair of metal layers adjacent to each other, and an insulating layer interposed between the pair of metal layers; a metal wiring board that is bonded to the pair of metal layers of the semiconductor element respectively via a pair of bonding materials, the metal wiring board including a pair of regions thereof respectively overlapping with the pair of metal layers in a plan view of the semiconductor device; and a separation portion provided between the semiconductor element and the metal wiring board, and separating the pair of regions of the metal wiring board.

### CROSS-REFERENCE TO RELATED APPLICATIONS

This application is based upon and claims the benefit of priority to Japanese Patent Application No. 2024-206883, filed on Nov. 28, 2024, the entire contents of which are incorporated herein by reference.

### BACKGROUND OF THE INVENTION

### 1. Technical Field

The present invention relates to a semiconductor device and a vehicle.

### 2. Description of the Related Art

Among semiconductor devices used in power conversion devices such as inverter devices, there is a semiconductor device in which a main electrode exposed on one surface of a semiconductor element and a metal wiring board are bonded to each other by a bonding material such as a solder. Some semiconductor elements used in this type of semiconductor device include a semiconductor element in which an exposed surface of a main electrode to be bonded to a single metal wiring board is divided into a plurality of regions by an insulating layer (for example, WO 2019/244492 A, WO 2021/075220 A, and JP 2024-048788 A).

### SUMMARY OF THE INVENTION

When the exposed surface of the main electrode of the semiconductor element to be bonded to the single metal wiring board is divided into the plurality of regions by the insulating layer, the melted bonding material between the metal wiring board and the main electrode of the semiconductor element may scatter and adhere to an unintended place in a process of bonding the metal wiring board and the main electrode of the semiconductor element. The bonding material adhering to and remaining in the unintended place can cause a product defect such as a malfunction of the semiconductor device.

The present invention has been made in view of such a point, and an object of the present invention is to prevent occurrence of a product defect due to scattering of a bonding material used for bonding a main electrode of a semiconductor element and a metal wiring board.

A semiconductor device according to one aspect of the present invention includes: a semiconductor element in which a plurality of metal layers adjacent to each other with an insulating layer interposed therebetween are exposed on a first surface; a metal wiring board that is bonded to the plurality of metal layers of the semiconductor element via bonding materials; and a separation portion that is provided between the semiconductor element and the metal wiring board, has a region overlapping with the insulating layer in plan view of the first surface, and separates a plurality of regions respectively overlapping with the plurality of metal layers in the metal wiring board.

According to the present invention, it is possible to prevent occurrence of a product defect due to scattering of a bonding material used for bonding a main electrode of a semiconductor element and a metal wiring board.

### BRIEF DESCRIPTION OF THE DRAWINGS

FIG. 1 is a top view illustrating a configuration example of a semiconductor device according to a first embodiment;

FIG. 2 is a cross-sectional view illustrating a configuration example of the semiconductor device taken along line with alternating long and short dashes A-A′ in FIG. 1;

FIG. 3 is an enlarged partial cross-sectional view of a bonding section between a semiconductor element and a metal wiring board in FIG. 2;

FIG. 4 is a diagram illustrating a configuration example of an inverter circuit using the semiconductor device according to the first embodiment;

FIGS. 5A and 5B are a top view (FIG. 5A) and a cross-sectional view (FIG. 5B) illustrating a configuration example of an upper surface electrode of the semiconductor element;

FIGS. 6A and 6B are a top view (FIG. 6A) illustrating an example of a plane shape of an insulating layer that separates a main electrode, and a top view (FIG. 6B) illustrating an example of a plane shape of a separation portion of the metal wiring board;

FIG. 7 is a perspective view of a bonding portion of the metal wiring board for the main electrode of the semiconductor element;

FIG. 8 is a cross-sectional view illustrating an example of a method of forming the separation portion of the metal wiring board;

FIGS. 9A and 9B are a top view (FIG. 9A) and a cross-sectional view (FIG. 9B) for describing an example of a bonding procedure between the main electrode of the semiconductor element and the metal wiring board;

FIG. 10 is a top view illustrating an example of a bridge that is formed in a case where the separation portion is not provided in the metal wiring board;

FIG. 11 is a cross-sectional view of a bonding section between the main electrode of the semiconductor element and the metal wiring board taken along line with alternating long and short dashes D-D′ in FIG. 10;

FIGS. 12A and 12B are a top view (FIG. 12A) illustrating an example of a plane shape of an insulating layer that separates a main electrode in a semiconductor device according to a second embodiment, and a top view (FIG. 12B) illustrating an example of a plane shape of a separation portion of a metal wiring board;

FIG. 13 is a top view for describing a configuration example of an upper surface electrode of a semiconductor element and a separation portion of a metal wiring board in a semiconductor device according to a third embodiment;

FIG. 14 is a cross-sectional view illustrating a configuration example of a metal wiring board in a semiconductor device according to a fourth embodiment;

FIG. 15 is a cross-sectional view for describing an example of a bonding procedure between a main electrode of a semiconductor element and a metal wiring board according to a fifth embodiment;

FIGS. 16A to 16C are cross-sectional views illustrating other configuration examples of the metal wiring board according to the fifth embodiment;

FIG. 17 is an exploded perspective view illustrating a method of forming a separation portion of a metal wiring board according to a sixth embodiment; and

FIG. 18 is a schematic plan view illustrating an example of a vehicle to which the semiconductor device according to the present invention is applied.

### DETAILED DESCRIPTION

Hereinafter, an embodiment of the present invention will be described in detail with reference to the drawings. Note that an X axis, a Y axis, and a Z axis in each of the drawings to be referred to are illustrated for the purpose of defining a plane and a direction in the exemplified semiconductor device or the like. The X, Y, and Z axes are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. In addition, in a case where each of the X direction, the Y direction, and the Z direction is associated with a direction indicated by an arrow (positive or negative) of the X axis, the Y axis, and the Z axis illustrated, a “positive side” or a “negative side” is added.

In the present specification, the Z direction may be referred to as an up-down direction. In the present specification, “above (on)” and “upper (upward)” are intended to refer to being on the positive side in the Z direction with respect to the reference surface, member, or position, for example, and “below (under)” and “lower (downward)” are intended to refer to being on the negative side in the Z direction with respect to the reference surface, member, or position, for example. For example, when it is described that “a member B is disposed above a member A”, the member B is disposed on the positive side in the Z direction when viewed from the member A. Further, when an “upper surface of the member A” is described, the surface is positioned at the end of the member A on the positive side in the Z direction and faces the positive side in the Z direction. In the present specification, “top view” is intended to refer to a plan view when a target article (for example, a semiconductor device) is viewed from the positive side in the Z direction. Such directions and surfaces are terms used for convenience of description. Thus, depending on, for example, an attachment posture of the semiconductor device, a correspondence relationship with directions of the X axis, the Y axis, and the Z axis may vary. For example, in the present specification, a surface of a semiconductor element facing a wiring board is referred to as a lower surface, and a surface opposite to the lower surface is referred to as an upper surface, but the terms are not limited thereto, and the surface facing the wiring board may be referred to as the upper surface, and the surface opposite thereto may be referred to as the lower surface. The lower surface and the upper surface of the semiconductor element may be referred to as side surfaces. Furthermore, an aspect ratio and a size relationship between the members in each drawing are merely schematically represented, and do not necessarily coincide with a relationship in the semiconductor device or the like actually manufactured. For convenience of description, it is also assumed that the size relationship between the members is exaggerated.

Furthermore, the semiconductor device exemplified in the following description may be applied to, for example, a power conversion device such as an industrial or vehicular inverter device. Thus, in the following description, detailed description of the same or similar configuration, function, operation, manufacturing method, and the like as those of the known semiconductor device will be omitted.

### First Embodiment

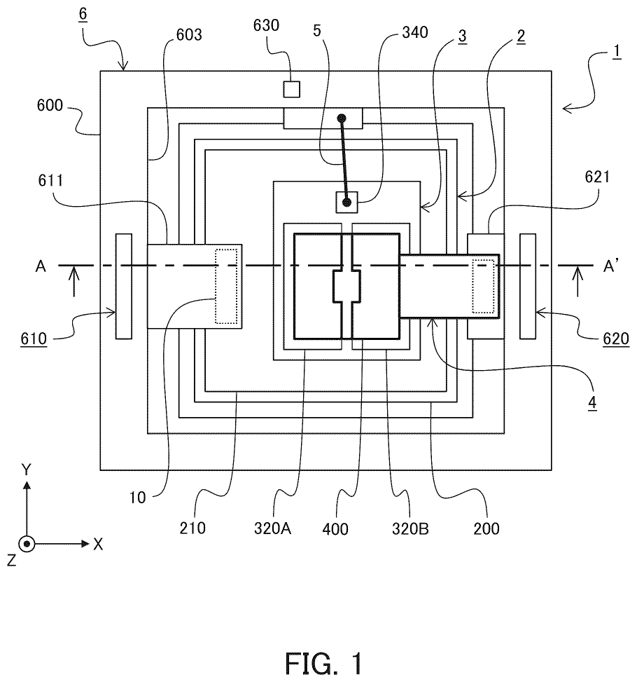

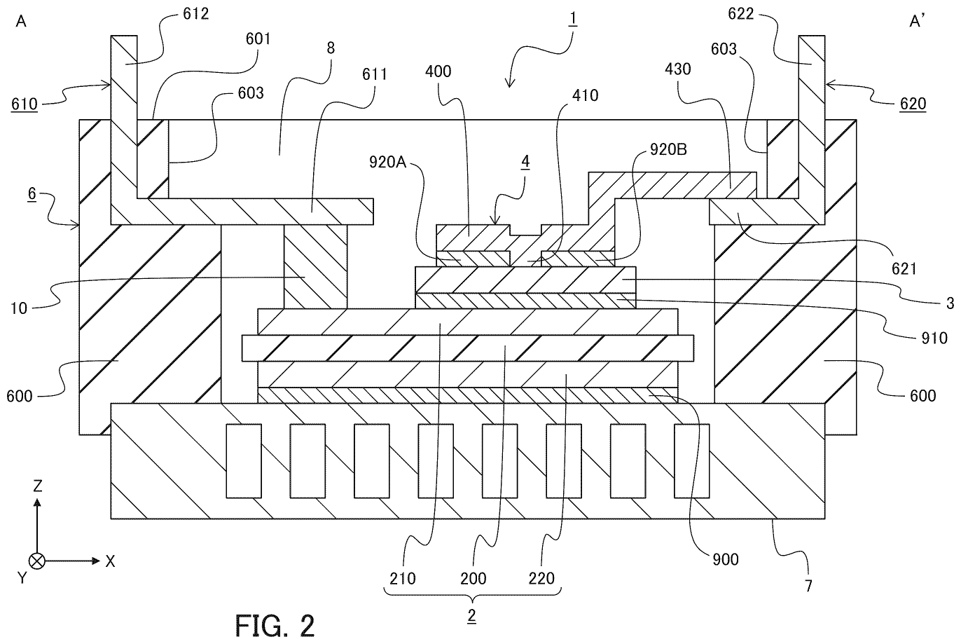

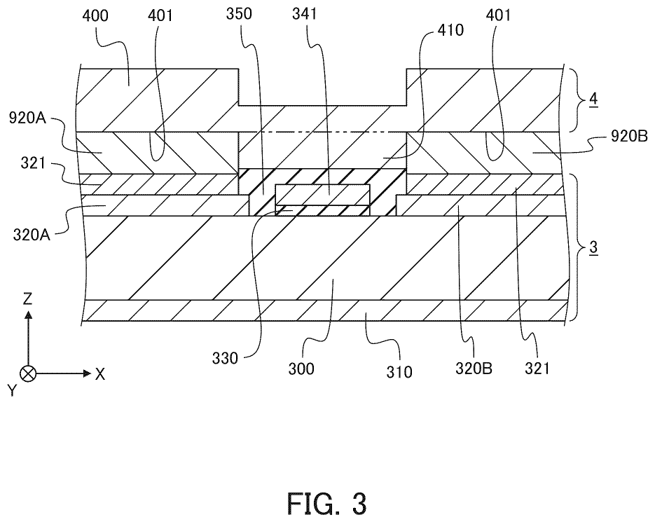

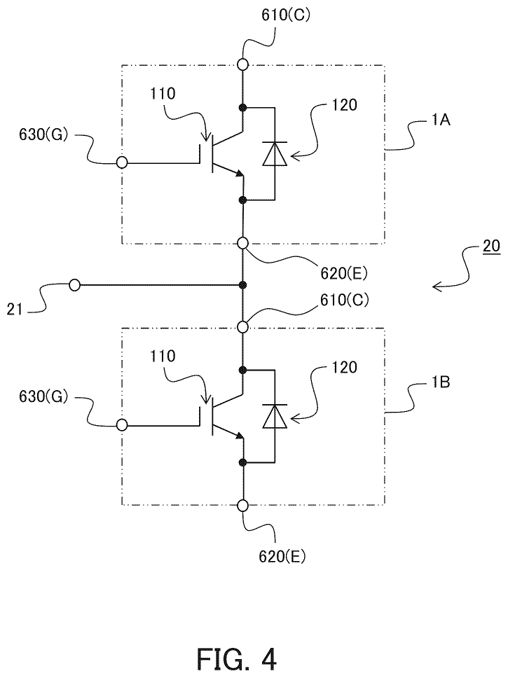

FIG. 1 is a top view illustrating a configuration example of a semiconductor device according to a first embodiment. FIG. 2 is a cross-sectional view illustrating a configuration example of the semiconductor device taken along line with alternating long and short dashes A-A′ in FIG. 1. FIG. 3 is an enlarged partial cross-sectional view of a bonding section between a semiconductor element and a metal wiring board in FIG. 2. FIG. 4 is a diagram illustrating a configuration example of an inverter circuit using the semiconductor device according to the first embodiment. In FIG. 2, hatching of a cross-sectional portion of a sealing material 8 for sealing a semiconductor element 3 or the like is omitted.

A semiconductor device 1 illustrated in FIGS. 1 to 3 includes a wiring board 2, the semiconductor element 3, a metal wiring board 4, a bonding wire 5, a case 6, a cooler 7, and the sealing material 8. The semiconductor device 1 is used, for example, as a circuit component for forming an inverter circuit. As an example, FIG. 4 illustrates a half-bridge inverter circuit 20 formed using two semiconductor devices 1A and 1B. Each of the first semiconductor device 1A and the second semiconductor device 1B in FIG. 4 can be the semiconductor device 1 illustrated in FIGS. 1 to 3. Each of the semiconductor devices 1A and 1B includes an insulated gate bipolar transistor (IGBT) element 110 which is a switching element, and a diode element 120 such as a free wheeling diode (FWD) element connected in anti-parallel to the IGBT element 110. The semiconductor element 3 exemplified in the present specification is a reverse conducting (RC)-IGBT element in which the IGBT element 110 and the diode element 120 are integrated with each other. In the half-bridge inverter circuit 20, an emitter terminal 620 of the first semiconductor device 1A and a collector terminal 610 of the second semiconductor device 1B are electrically connected to an intermediate terminal 21.

The wiring board 2 includes an insulating substrate 200, a first conductive layer 210 provided on an upper surface of the insulating substrate 200, and a second conductive layer 220 provided on a lower surface of the insulating substrate 200. The wiring board 2 can be, for example, a direct copper bonding (DCB) substrate or an active metal brazing (AMB) substrate. The wiring board 2 may be referred to as a wiring substrate, a stacked substrate, or the like.

The insulating substrate 200 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 200 is not limited to the ceramic substrate. Examples of the insulating substrate 200 may include a substrate obtained by molding an insulating resin such as an epoxy resin, a substrate obtained by impregnating a base material such as a glass fiber with an insulating resin, a substrate obtained by coating a surface of a flat-plate-shaped metal core with an insulating resin, or the like.

The first conductive layer 210 is one of wiring components electrically connecting a lower surface electrode (a first main electrode 310 in FIG. 3) of the semiconductor element 3 and the collector terminal 610 of the case 6, and can also be a heat conducting component for dissipating heat generated by the semiconductor element 3 to the outside of the semiconductor device 1. The second conductive layer 220 is a heat conducting component for dissipating heat generated by the semiconductor element 3 to the outside of the semiconductor device 1. The first conductive layer 210 and the second conductive layer 220 are formed using, for example, a metal plate or metal foil such as copper or aluminum. The conductive layer in the wiring board 2 may be referred to as a conductor layer, a conductor plate, or the like.

For example, as illustrated in FIG. 2, the wiring board 2 is disposed on an upper surface of the cooler 7. The second conductive layer 220 of the wiring board 2 and the cooler 7 are bonded by a bonding material 900 such as a solder. Instead of the bonding material 900, a thermal conductive material such as thermal grease or thermal compound may be used. The cooler 7 is not limited to one having a specific configuration. The cooler 7 can include, for example, a flat-plate-shaped base member bonded to the wiring board 2, and a water jacket attached below the base member. In the cooler 7, fins may be provided in a refrigerant flow path defined by the base member and the water jacket (see FIG. 2). The cooler 7 may be any component in the semiconductor device 1. The semiconductor device 1 may include a member having a favorable thermal conductivity, such as a metal plate, instead of the cooler 7, and the wiring board 2 may be bonded to an upper surface of the member.

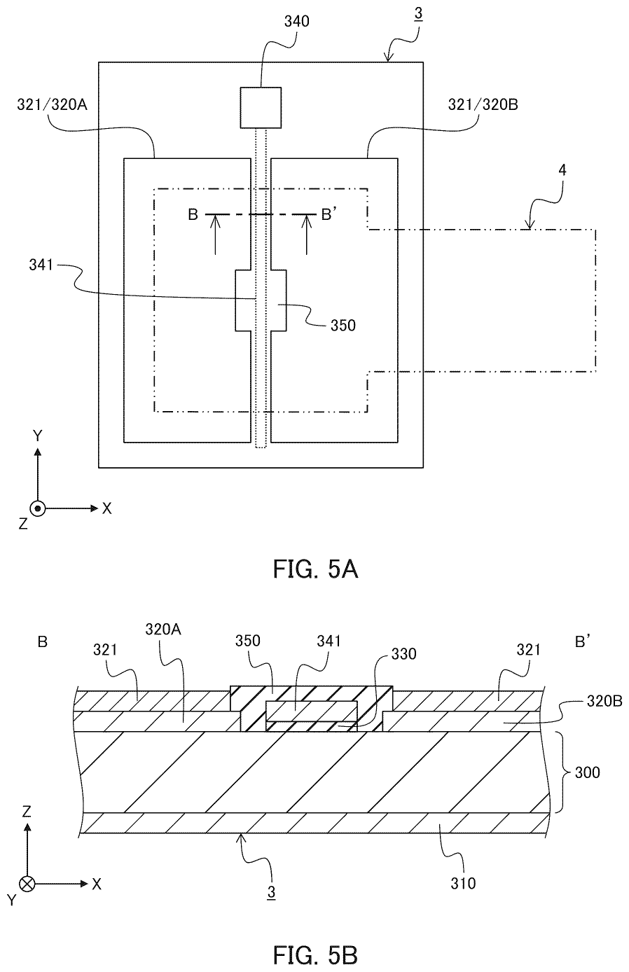

The semiconductor element 3 is disposed on an upper surface of the wiring board 2. The semiconductor element 3 can be the above-described RC-IGBT element, and as illustrated in FIG. 3, the first main electrode 310 is provided on a lower surface of a semiconductor layer 300. Second main electrodes 320A and 320B and a runner portion 341 passing between the two second main electrodes 320A and 320B are provided on an upper surface of the semiconductor layer 300. The runner portion 341 is a conductive layer that can function as a gate of the switching element (IGBT element 110) illustrated in FIG. 4, and has one end connected to a gate electrode 340 (see FIGS. 1 and 5A). When the switching element of the semiconductor element 3 is the IGBT element 110, the first main electrode 310 on a lower surface side may be referred to as a collector electrode, and the second main electrodes 320A and 320B on an upper surface side may be referred to as emitter electrodes. The runner portion 341 is disposed on the upper surface of the semiconductor layer 300 via a gate oxide film (insulating film) 330, and is covered with an insulating layer 350. Plating layers 321 are formed on upper surfaces of the second main electrodes 320A and 320B, and the plating layer 321 on the upper surface of the second main electrode 320A and the plating layer 321 on the upper surface of the second main electrode 320B are separated from each other by the insulating layer 350.

The two second main electrodes 320A and 320B in the following description include the plating layers 321 on the upper surfaces thereof for convenience. The semiconductor layer 300 can be formed by diffusing predetermined impurities into a semiconductor substrate such that the semiconductor element 3 operates as the switching element (for example, the IGBT element 110) and the diode element 120. The switching element formed in the semiconductor element 3 may have a trench structure or a planar structure. The semiconductor substrate can be a silicon substrate, but is not limited to a substrate of a specific semiconductor material. The semiconductor substrate may be, for example, a substrate using a wide band gap semiconductor, such as a silicon carbide (SiC) substrate or a gallium nitride (GaN) substrate. In the following description, the second main electrode 320A and the second main electrode 320B provided on an upper surface of the semiconductor element 3 may be referred to as a first pad 320A and a second pad 320B, respectively. The first pad 320A and the second pad 320B in the following description can include the plating layer 321 on the upper surface for convenience, and exposed surfaces of the first pad 320A and the second pad 320B may be the upper surfaces of the plating layers 321.

In the semiconductor device 1 according to the present embodiment, the first main electrode 310 (see FIG. 3) provided on a lower surface of the semiconductor element 3 is bonded to the first conductive layer 210 of the wiring board 2 by a bonding material 910. The first conductive layer 210 of the wiring board 2 is electrically connected to the collector terminal 610 provided in the case 6 via, for example, a conductive block 10 disposed outside a region that is bonded to the semiconductor element 3 on an upper surface of the first conductive layer 210. The conductive block 10 is bonded to each of the first conductive layer 210 of the wiring board 2 and an inner terminal portion 611 of the collector terminal 610 by, for example, a bonding material (not illustrated). The conductive block 10 may be integrally formed with the first conductive layer 210 of the wiring board 2. A method of electrically connecting the first conductive layer 210 of the wiring board 2 and the inner terminal portion 611 of the collector terminal 610 is not limited to a method using the conductive block 10. For example, the semiconductor device 1 may have a configuration in which the inner terminal portion 611 of the collector terminal 610 is bent downward, and the inner terminal portion 611 and the first conductive layer 210 of the wiring board 2 are bonded by a bonding material.

In the semiconductor element 3, each of the first pad 320A and the second pad 320B provided on the upper surface (actually, the plating layers 321 on the upper surfaces thereof) is bonded to a first bonding portion 400 of the metal wiring board 4 by a bonding material 920A and a bonding material 920B. The metal wiring board 4 is formed by bending a metal plate such as a copper plate, and includes the first bonding portion 400 and a second bonding portion 430. The first bonding portion 400 is a portion bonded to the first pad 320A and the second pad 320B of the semiconductor element 3, and the second bonding portion 430 is a portion bonded to the emitter terminal 620 provided in the case 6. The first bonding portion 400 is provided with a separation portion 410 that protrudes downward from a lower surface 401 facing the semiconductor element 3 and separates the bonding material 920A on the first pad 320A and the bonding material 920B on the second pad 320B. In the metal wiring board 4 illustrated in FIG. 3, the separation portion 410 can protrude downward (toward the negative side in the Z direction) from a line with alternating long and two short dashes continuous with the lower surface 401 of the first bonding portion 400. A shape, a manufacturing method, and the like of the separation portion 410 are described below.

In the semiconductor element 3, the gate electrode 340 provided on the upper surface is electrically connected to a gate terminal 630 provided in the case 6 by the bonding wire 5. As described below with reference to FIG. 5A and the like, the gate electrode 340 of the semiconductor element 3 is connected to one end of the runner portion 341 passing between the first pad 320A and the second pad 320B in an extending direction (Y direction), and for example, a plating layer (not illustrated) is formed on an upper surface of the gate electrode 340. The plating layer on the upper surface of the gate electrode 340 is exposed on the upper surface of the semiconductor element 3.

The case 6 of the semiconductor device 1 described above includes an insulating member 600 having a square ring shape surrounding the wiring board 2 in X-Y plan view, and the collector terminal 610, the emitter terminal 620, and the gate terminal 630 attached to the insulating member 600. The case 6 is attached to the cooler 7 by an adhesive or by fastening using a bolt. A hollow portion surrounded by an inner peripheral wall surface 603 of the insulating member 600 is filled with the sealing material 8 for sealing the wiring board 2, the semiconductor element 3, the metal wiring board 4, and the like. An opening region of an upper surface 601 of the insulating member 600 may be covered with a lid member (not illustrated). In FIG. 2, an outer terminal portion 612 of the collector terminal 610 and an outer terminal portion 622 of the emitter terminal 620 extending upward from the upper surface 601 of the insulating member 600 may be bent along the upper surface 601 of the insulating member 600.

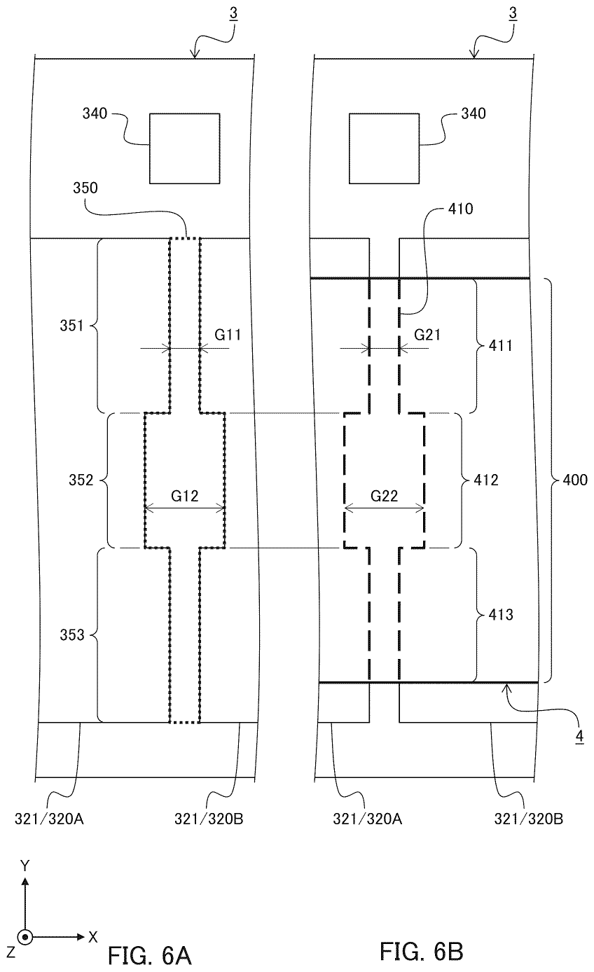

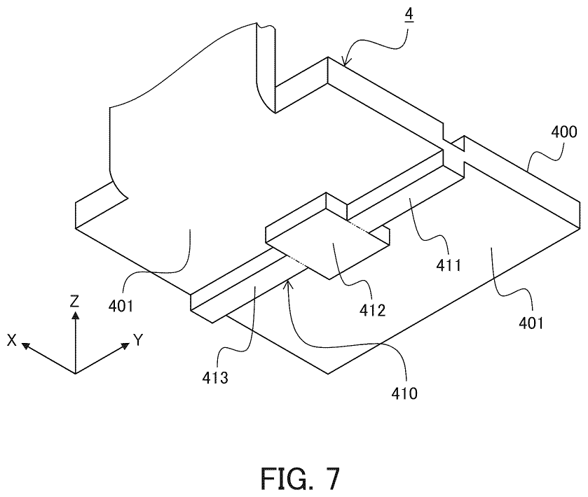

FIGS. 5A and 5B are a top view (FIG. 5A) and a cross-sectional view (FIG. 5B) illustrating a configuration example of an upper surface electrode of the semiconductor element. FIGS. 6A and 6B are a top view (FIG. 6A) illustrating an example of a plane shape of the insulating layer that separates the main electrode, and a top view (FIG. 6B) illustrating an example of a plane shape of the separation portion of the metal wiring board. FIG. 7 is a perspective view of a bonding portion of the metal wiring board for the main electrode of the semiconductor element.

As illustrated in FIGS. 5A and 5B, the first pad 320A and the second pad 320B, which are the second main electrodes (emitter electrodes), and the gate electrode 340 are provided on the upper surface of the semiconductor element 3 in which the IGBT element 110 is formed. The gate electrode 340 is exposed at a position near one end side (an end side on the positive side in the Y direction in FIG. 5A) on the upper surface of the semiconductor element 3 having a rectangular shape in X-Y plan view at a central portion in the X direction. The gate electrode 340 includes the runner portion 341 extending toward an end side on the negative side in the Y direction, and the runner portion 341 is covered with the insulating layer 350. The first pad 320A and the second pad 320B are arranged side by side in the X direction with the runner portion 341 extending in the Y direction interposed therebetween. The first pad 320A and the second pad 320B are separated by the insulating layer 350 covering the runner portion 341 on the upper surface of the semiconductor element 3.

For example, as illustrated in FIG. 6A, the insulating layer 350 that separates the first pad 320A and the second pad 320B may be provided so as to have a wide section (second section) 352 that is wider than both end sides at a central portion in the extending direction (Y direction). On the other hand, in a portion of the runner portion 341 passing between the first pad 320A and the second pad 320B, a dimension (width) in the X direction orthogonal to the extending direction can be constant in the extending direction. In this example, an end side of each of the first pad 320A and the second pad 320B extending along the runner portion 341 can have a section in which a gap with the runner portion 341 is a first gap and a section in which the gap is a second gap wider than the first gap. A width G12 of the wide section 352 and widths G11 of a first section 351 on the positive side in the Y direction and a third section 353 on the negative side in the Y direction with respect to the wide section 352 are not limited to specific values. In an example, the widths G11 of the first section 351 and the third section 353 can be 0.166 mm, and the width G12 of the wide section 352 can be 0.520 mm.

The separation portion 410 corresponding to the insulating layer 350 when disposed on the semiconductor element 3 is provided on the lower surface 401 (see FIG. 3) of the first bonding portion 400 of the metal wiring board 4 bonded to the first pad 320A and the second pad 320B of the semiconductor element 3. In a case where the insulating layer 350 has the wide section 352, the separation portion 410 having a wide section 412 corresponding to the plane shape of the insulating layer 350 is provided on the lower surface 401 of the first bonding portion 400 of the metal wiring board 4 as illustrated in FIGS. 6B and 7. A width G22 of the wide section 412 of the separation portion 410 and the width G12 of the wide section 352 of the insulating layer 350 can satisfy G22≥G12, and it is more preferable that G22=G12. Widths G21 of a first section 411 and a third section 413 of the separation portion 410 and the widths G11 of the first section 351 and the third section 353 of the insulating layer 350 can satisfy G21≥G11, and it is more preferable that G21=G11.

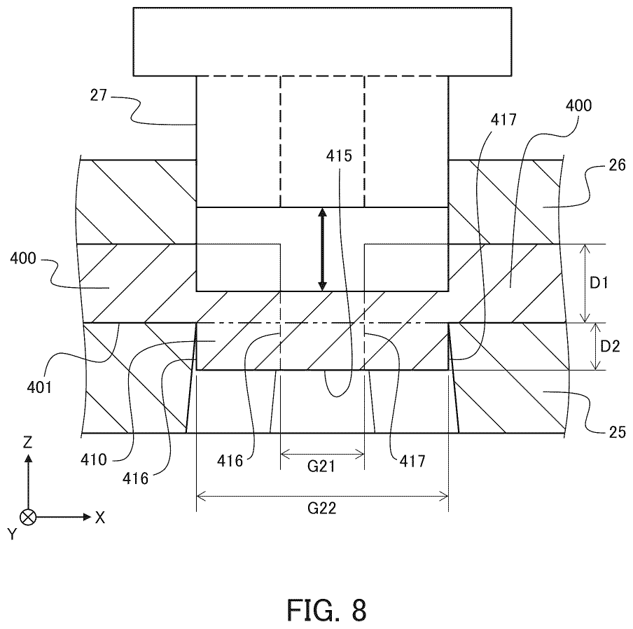

The separation portion 410 of the metal wiring board 4 can be formed by, for example, press working (half punching) using a mold as illustrated in FIG. 8. The mold includes a die 25, a stripper 26, and a punch 27. In the case of the half punching, the punch 27 is pressed into the first bonding portion 400 by a pressing amount D2 (<D1) that is not enough to punch the flat-plate-shaped first bonding portion 400 sandwiched between the die 25 and the stripper 26 and having a thickness D1. A plane shape of a lower end surface of the punch 27 is substantially the same as the plane shape of the separation portion 410, and the punch 27 has a first section, a wide section (second section), and a third section. When the punch 27 is pressed downward against an upper surface of the first bonding portion 400 of the metal wiring board 4, a portion of the first bonding portion 400 that is in contact with the lower end surface of the punch 27 is displaced downward and protrudes downward from the lower surface 401 to serve as the separation portion 410. In the separation portion 410 formed by the half punching, a distal end surface 415 is substantially parallel to the lower surface 401 of the first bonding portion 400, and a pair of side surfaces 416 and 417 connected to the distal end surface 415 and the lower surface 401 of the first bonding portion 400 is substantially perpendicular to the lower surface 401 of the first bonding portion 400. FIG. 8 illustrates a portion of the separation portion 410 at which the wide section 412 is formed, and the first section 411 and the third section 413 having smaller widths than the wide section 412 are formed on the positive side in the Y direction (a back side in the drawing) and the negative side in the Y direction (a front side in the drawing) with respect to the portion illustrated in FIG. 8. The pressing amount D2 can be set based on, for example, thicknesses of the bonding materials 920A and 920B that bond the first pad 320A and the second pad 320B of the semiconductor element 3 and the first bonding portion 400 of the metal wiring board 4. For example, in a case where the thicknesses of the bonding materials 920A and 920B that can ensure bonding reliability are 0.3 mm, the thickness D1 of the first bonding portion 400 of the metal wiring board 4 can be set to 0.5 mm, and the pressing amount D2 can be set to 0.3 mm. In a case where the pressing amount D2 is set to 0.3 mm, a height of the separation portion 410 to be formed from the lower surface 401 of the first bonding portion 400 is 0.3 mm. Therefore, for example, as illustrated in FIG. 3, the bonding materials 920A and 920B can have predetermined thicknesses (for example, 0.3 mm) in a state in which the distal end surface (lower end surface) of the separation portion 410 is in contact with the insulating layer 350.

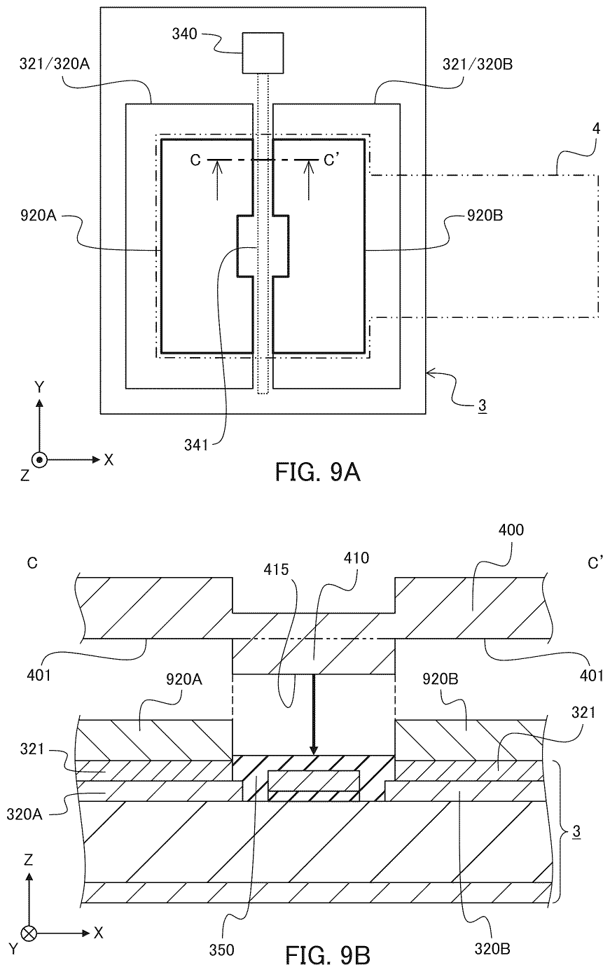

FIGS. 9A and 9B are a top view (FIG. 9A) and a cross-sectional view (FIG. 9B) illustrating an example of a bonding procedure between the main electrode of the semiconductor element and the metal wiring board. When the first pad 320A and the second pad 320B of the semiconductor element 3 are bonded to the metal wiring board 4, first, the bonding materials 920A and 920B are disposed on the first pad 320A and the second pad 320B of the semiconductor element 3 as illustrated in FIGS. 9A and 9B. The bonding materials 920A and 920B to be disposed can be plate solders whose plane shapes substantially coincide with shapes of overlapping regions between the exposed surfaces of the first pad 320A and the second pad 320B (actually, the plating layers 321 on upper surfaces thereof) and the metal wiring board 4, respectively. After the bonding materials (plate solders) 920A and 920B are disposed, the metal wiring board 4 is disposed such that the first bonding portion 400 is disposed on the bonding materials 920A and 920B as illustrated in FIG. 9B. At this time, the metal wiring board 4 is disposed such that the separation portion 410 formed in the first bonding portion 400 is fitted between the bonding material 920A and the bonding material 920B and the entire distal end surface (lower end surface) 415 of the separation portion 410 is in contact with an upper surface of insulating layer 350 (see FIG. 3). Thereafter, the bonding materials 920A and 920B are heated and melted to bond the first pad 320A and the second pad 320B to the metal wiring board 4. At this time, the bonding material 920A and the bonding material 920B are separated from each other by the separation portion 410 of the metal wiring board 4 that is in contact with the insulating layer 350 of the semiconductor element 3. Therefore, it is possible to prevent a bridge from being formed by the melted bonding material 920A and bonding material 920B on the insulating layer 350. That is, by using the metal wiring board 4 in which the separation portion 410 is formed in the first bonding portion 400, it is possible to prevent the formation of a bridge caused by scattering of the bonding materials that bond the first pad 320A and the second pad 320B of the semiconductor element 3 and the metal wiring board 4. The bonding materials 920A and 920B for bonding the main electrodes (the first pad 320A and the second pad 320B) of the semiconductor element 3 and the metal wiring board 4 are not limited to the plate solders. The bonding materials 920A and 920B before bonding may be paste-like bonding materials called cream solders, solder pastes, or the like.

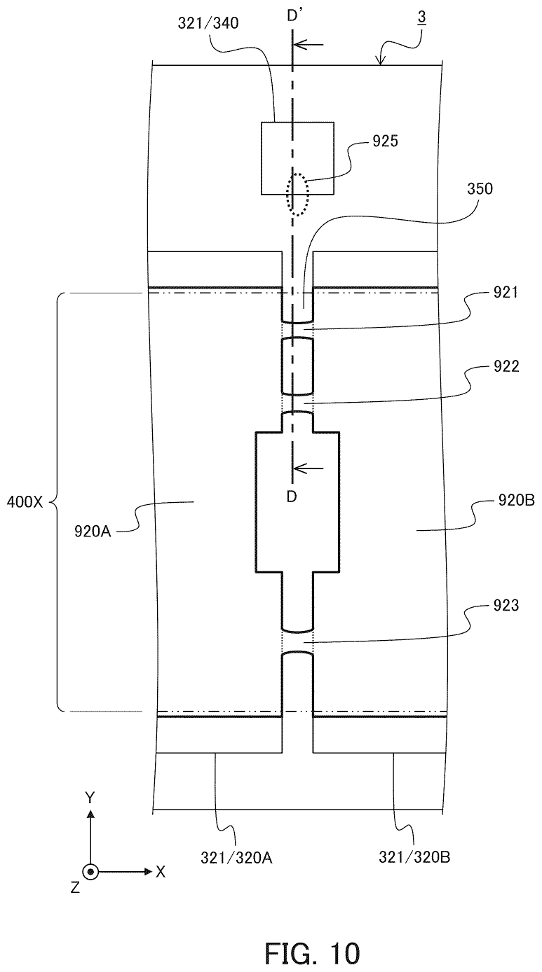

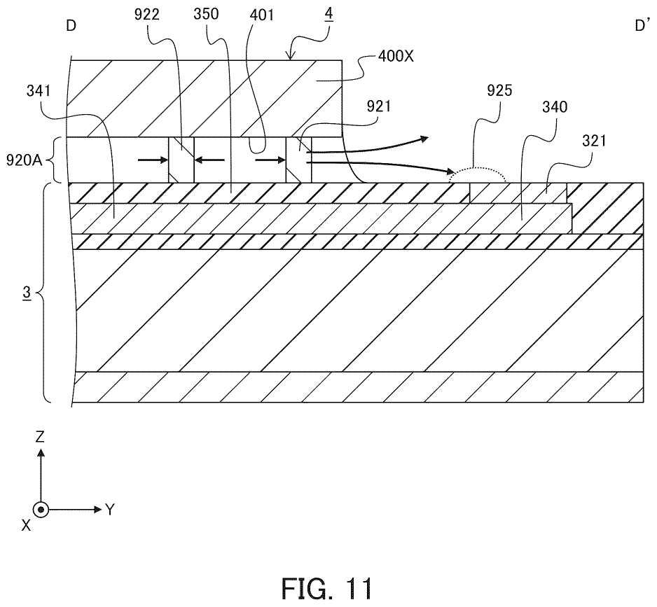

FIG. 10 is a top view illustrating an example of a bridge that is formed in a case where the separation portion is not provided in the metal wiring board. FIG. 11 is a cross-sectional view of a bonding section between the main electrode of the semiconductor element and the metal wiring board taken along line with alternating long and short dashes D-D′ in FIG. 10.

A first bonding portion 400X of a metal wiring board 4 illustrated in FIGS. 10 and 11 is different from the first bonding portion 400 according to the present embodiment in that the separation portion 410 is not provided on a lower surface 401. In a case where the first bonding portion 400X in which the separation portion 410 is not provided on the lower surface 401 is bonded to a first pad 320A and a second pad 320B of a semiconductor element 3 by bonding materials 920A and 920B, the first bonding portion 400X and an insulating layer 350 of the semiconductor element 3 are separated from each other. In a case where the first bonding portion 400X and the insulating layer 350 are separated from each other, a portion of the melted bonding material may flow out onto the insulating layer 350 of the semiconductor element 3 or remain, as a result of which bridges 921 to 923 that connect the bonding material 920A and the bonding material 920B may be formed. As illustrated in FIG. 11, the bridges 921 to 923 may be in contact with the insulating layer 350 and the first bonding portion 400X of the metal wiring board 4 and generate a gap (closed gap) that is closed from the outside on the insulating layer 350. When air in the closed gap generated on the insulating layer 350 is expanded by, for example, heating for melting the bonding material, the bridges 921 to 923 are pushed out toward an end portion side of the insulating layer 350 in an extending direction (Y direction) by a pressure of the expanded air and scatter. The scattering of the bridges 921 to 923 can also occur, for example, by a heating process after a bonding process, the expansion of the air in the closed gap due to a gas or the like generated from the insulating layer 350, or the like. When the scattering bonding material adheres to and remains on a gate electrode 340 like a bonding material 925 indicated by a dotted line in FIGS. 10 and 11, for example, a connection failure between the gate electrode 340 and a bonding wire 5 can occur. In addition, in a case where an electrode different from the first pad 320A, the second pad 320B, and the gate electrode 340 is exposed on an upper surface of the semiconductor element 3, a short circuit can occur due to the scattering bonding material. That is, since the semiconductor devices described in WO 2019/244492 A, WO 2021/075220 A, JP 2024-048788 A, and the like do not have a portion corresponding to the separation portion 410 on the lower surface 401 of the first bonding portion 400 according to the present embodiment, a product defect due to the scattering of the bridge of the bonding material formed on the insulating layer is likely to occur.

On the other hand, in the semiconductor device 1 according to the present embodiment, as described above, the separation portion 410 provided in the metal wiring board 4 can prevent the formation of the bridge on the insulating layer 350, so that a product defect due to scattering of the bonding material can be prevented.

The semiconductor device 1 according to the first embodiment is not limited to a configuration including one semiconductor element 3 described above with reference to FIGS. 1, 2, and 4. The semiconductor device 1 may include a plurality of semiconductor elements 3. Each of the plurality of semiconductor elements 3 is not limited to one in which the switching element (for example, the IGBT element 110) and the diode element 120 described above are formed. The plurality of semiconductor elements may include a semiconductor element in which the switching element (for example, IGBT element 110) is formed and a semiconductor element in which the diode element 120 is formed. In the semiconductor device 1 including the plurality of semiconductor elements 3, for example, the half-bridge inverter circuit 20 illustrated in FIG. 4 may be formed.

The switching element of the semiconductor element 3 is not limited to the IGBT element 110 described above. Examples of the switching element may include a power metal oxide semiconductor field effect transistor (MOSFET) element and a bipolar junction transistor (BJT) element. When the switching element is a MOSFET element, the main electrode on the lower surface side of the semiconductor element 3 may be referred to as a drain electrode, and the main electrode on the upper surface side may be referred to as a source electrode. The diode element 120 is not limited to the FWD element. Examples of the diode element 120 may include a Schottky barrier diode (SBD) element, a junction barrier Schottky (JBS) diode element, a merged PN Schottky (MPS) diode element, a PN diode element, or the like. The substrate (a substrate that can serve as the semiconductor layer 300 in FIGS. 3 and 5B) on which the switching element such as the IGBT element 110, the diode element, and the like are formed is not limited to the silicon substrate as described above, and may be, for example, a silicon carbide (SiC) substrate, a gallium nitride (GaN) substrate, or the like. In addition, the switching element and the diode element formed in the semiconductor element 3 are not limited to those having a specific structure. For example, the switching element may have a trench structure or a planar structure.

The electrode provided on the upper surface of the semiconductor element 3 in which the switching element is formed may include an auxiliary electrode different from the main electrode (emitter electrode) and the gate electrode described above. For example, the auxiliary electrode can be an auxiliary emitter electrode or an auxiliary source electrode electrically connected to the main electrode on the upper surface side. The auxiliary emitter electrode or the auxiliary source electrode is connected to a drive circuit that generates a control signal to be applied to the gate electrode. The drive circuit uses an emitter potential from the auxiliary emitter electrode or a source potential of the auxiliary source electrode as a reference potential with respect to a potential (gate potential) of the control signal. The auxiliary electrode may be a temperature sensing electrode electrically connected to a temperature sensing unit that may be included in, for example, the inverter device, and measures a temperature of the semiconductor element 3.

The second bonding portion 430 (see FIG. 2) in the metal wiring board 4 bonded to the main electrodes 320A and 320B on the upper surface of the semiconductor element 3 may be bonded to the conductive layer of the wiring board 2 instead of being bonded to the emitter terminal 620 of the case 6. The main electrodes 320A and 320B on the upper surface of the semiconductor element 3 may be bonded to an inner terminal portion 621 of the emitter terminal 620 of the case 6 instead of the metal wiring board 4. In this case, a separation portion corresponding to the separation portion 410 of the metal wiring board 4 described above is formed on a surface of the inner terminal portion 621 of the emitter terminal 620 that faces the insulating layer 350 of the semiconductor element 3.

The semiconductor device to which the metal wiring board 4 is applicable as described in the present embodiment and each of the following embodiments is not limited to the semiconductor device including the case 6 illustrated in FIGS. 1 and 2. The semiconductor device may be, for example, a semiconductor device such as a dual inline package (DIP) manufactured by sealing the semiconductor element 3 or the like by transfer molding or compression molding using a mold. In this type of semiconductor device, for example, the second bonding portion 430 in the metal wiring board 4 may extend to the outside of the device as an outer lead. Furthermore, the semiconductor device may have a configuration in which the wiring board 2 and the cooler 7 are integrated with each other, such as a configuration in which the conductive layer 210 is formed on the upper surface of the cooler 7 via an insulating layer, and the insulating substrate 200 and the conductive layer 220 are omitted.

### Second Embodiment

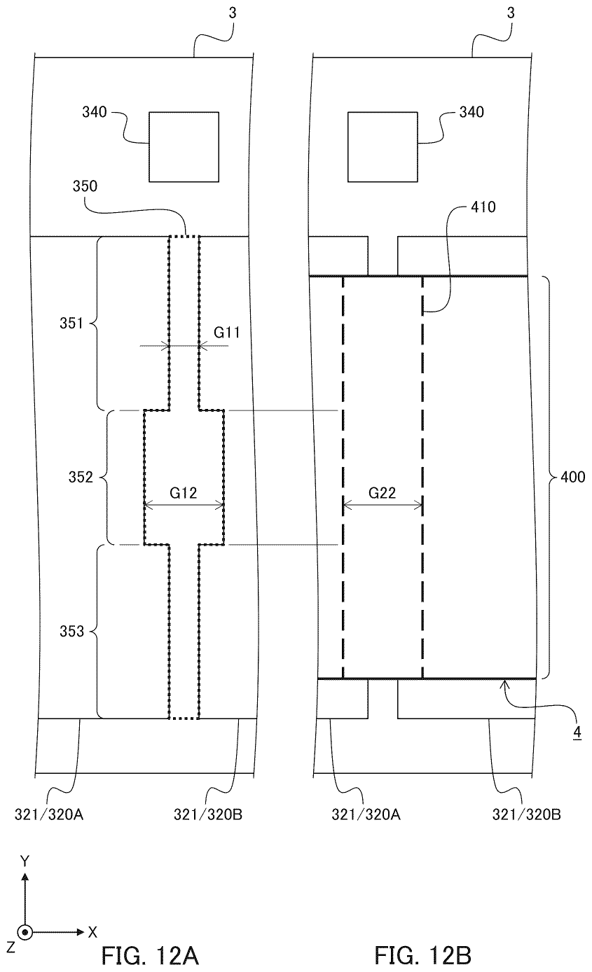

FIGS. 12A and 12B are a top view (FIG. 12A) illustrating an example of a plane shape of an insulating layer that separates a main electrode in a semiconductor device according to a second embodiment, and a top view (FIG. 12B) illustrating an example of a plane shape of a separation portion of a metal wiring board.

In the present embodiment, variations of a shape of a separation portion 410 formed on a metal wiring board 4 will be described. In order to simplify the description, main electrodes (emitter electrodes) on an upper surface of a semiconductor element 3 bonded to the metal wiring board 4 are assumed to be the first pad 320A and the second pad 320B exemplified in the first embodiment (see FIG. 6A). That is, as illustrated in FIG. 12A, a first pad 320A and a second pad 320B separated by an insulating layer 350 extending in the Y direction are provided on the upper surface of the semiconductor element 3. The insulating layer 350 has a wide section 352 having a width (a dimension in the X direction) larger than a first section 351 on one end side and a third section 353 on the other end side in an extending direction at a central portion in the extending direction (Y direction) in X-Y plan view. In a first bonding portion 400 of the metal wiring board 4 bonded to the first pad 320A and the second pad 320B separated by the insulating layer 350 having such a plane shape, the separation portion 410 in which a plane shape of a distal end surface is a single rectangle (oblong) may be formed. In other words, as illustrated in FIG. 12B, the separation portion 410 may be formed such that the plane shape of the distal end surface has a constant width G22 from one end to the other end in the extending direction of the insulating layer 350. The width G22 of the separation portion 410 is set such that a relationship with a width G12 of the wide section 352 of the insulating layer 350 is G22≥G12, and more preferably, G22=G12.

The separation portion 410 of the metal wiring board 4 according to the present embodiment has a simpler shape than the separation portion 410 of the first embodiment, and is formed to have a dimension corresponding to the width G12 of the wide section 352 of the insulating layer 350. Therefore, for example, it is possible to reduce the variations of the shape of the separation portion 410 for each metal wiring board 4 when the separation portion 410 is formed by press working. In the present embodiment, a case where the wide section 352 is provided in the insulating layer 350 of the semiconductor element 3 is taken as an example, but as exemplified in WO 2019/244492 A and WO 2021/075220 A, the insulating layer 350 of the semiconductor element 3 may have a constant width from one end to the other end in the extending direction (Y direction).

### Third Embodiment

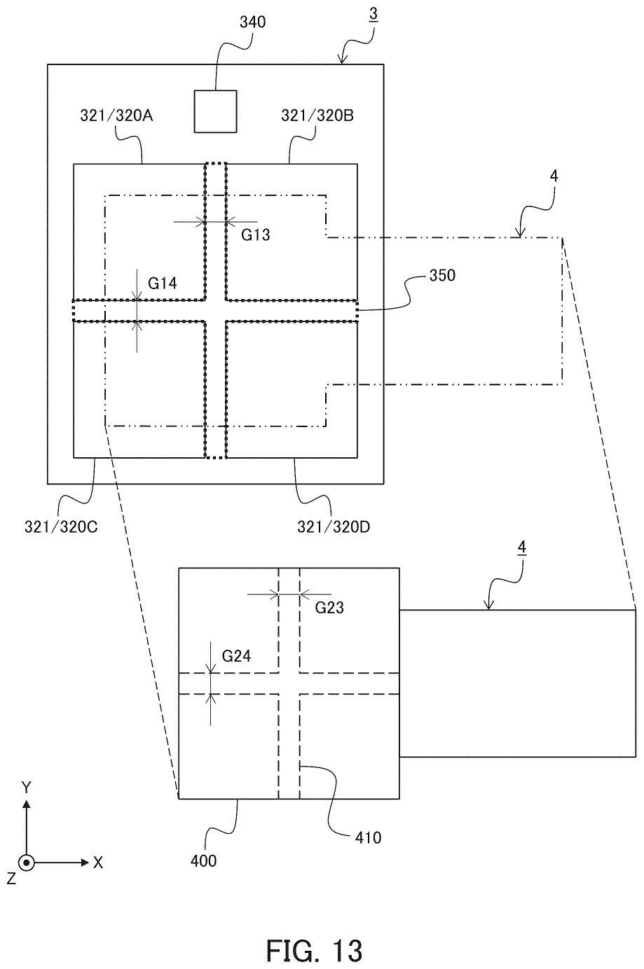

FIG. 13 is a top view for describing a configuration example of an upper surface electrode of a semiconductor element and a separation portion of a metal wiring board in a semiconductor device according to a third embodiment.

In the present embodiment, variations of main electrodes (emitter electrodes) provided on an upper surface of a semiconductor element 3 and a corresponding shape of a separation portion 410 of a metal wiring board 4 will be described. The main electrodes of the semiconductor element 3 bonded to the single metal wiring board 4 is not limited to two main electrodes 320A and 320B described above. For example, as illustrated in FIG. 13, four main electrodes 320A to 320D and a gate electrode 340 may be provided on the upper surface of the semiconductor element 3. A plating layer 321 is formed on an upper surface of each of the four main electrodes 320A to 320D and the gate electrode 340 and is exposed as a part of each electrode. All of the four main electrodes 320A to 320D illustrated in FIG. 13 can be emitter electrodes of a switching element (for example, an IGBT element 110), and are separated and arranged in a 2×2 matrix form by a cross-shaped insulating layer 350 in X-Y plan view. The cross-shaped insulating layer 350 can be an example of an insulating layer in which a first insulating layer extending in a first direction and a second insulating layer extending in a second direction different from the first direction intersect each other. From another point of view, the cross-shaped insulating layer 350 can be an example of an insulating layer having an origin region that is the center of the cross shape and first to fourth extending regions extending from the origin region in four different directions. Widths (dimensions in the X direction) G13 of two extending regions extending in the Y direction from the origin region in the cross-shaped insulating layer 350 and widths (dimensions in the Y direction) G14 of two extending regions extending in the X direction are not limited to specific values. The width G13 of the extending region extending in the Y direction may be different from the width G14 of the extending region extending in the X direction. The cross-shaped insulating layer 350 may have a wide section 352 described in the first embodiment.

The cross-shaped separation portion 410 corresponding to the insulating layer 350 in plan view is formed at a first bonding portion 400 of the metal wiring board 4 bonded to the four main electrodes (pads) 320A to 320D separated by the insulating layer 350 whose plane shape is a cross shape. The cross-shaped separation portion 410 can be an example of a separation portion in which a first separation portion extending in the first direction and a second separation portion extending in the second direction intersect each other. From another point of view, the cross-shaped separation portion 410 can be an example of a separation portion having an origin region and first to fourth partial protruding regions respectively extending from the origin region in four directions different from one another. A position of the origin region (the center of the cross shape) of the separation portion 410 on a lower surface of the first bonding portion 400 of the metal wiring board 4 is set according to a position of the first bonding portion 400 disposed above the semiconductor element 3 at the time of bonding and a position of an intersection region (the origin region which is the center of the cross shape) in the insulating layer 350. A width G23 of the partial protruding region extending in the Y direction in the separation portion 410 is set such that a relationship with the width G13 of the extending region extending in the Y direction of the insulating layer 350 is G23≥G13, and more preferably, G23=G13. Similarly, a width G24 of the partial protruding region extending in the X direction in the separation portion 410 is set such that a relationship with the width G14 of the extending region extending in the X direction of the insulating layer 350 is G24≥G14, and more preferably, G24=G14.

The arrangement of the main electrodes on the upper surface of the semiconductor element 3 to be bonded to the single metal wiring board 4 is not limited to the arrangement in the 2×2 matrix form illustrated in FIG. 13. The arrangement of the main electrodes to be bonded to the single metal wiring board 4 may be, for example, arrangement in an N×M (N and M are arbitrary integers, and N may be equal to M (N=M)) matrix form, or other arrangements. For example, in the arrangement in the N×M matrix form, two main electrodes adjacent to each other with an insulating layer as a boundary may be replaced with one main electrode. For example, the extending region passing between the third main electrode 320C and the fourth main electrode 320D in the cross-shaped insulating layer 350 illustrated in FIG. 13 may be omitted, and the third main electrode 320C and the fourth main electrode 320D may be replaced with one main electrode. In this example, a plane shape of the separation portion 410 is an inverted T shape having a partial protruding region extending in the X direction and a partial protruding region extending from the partial protruding region in the +Y direction.

### Fourth Embodiment

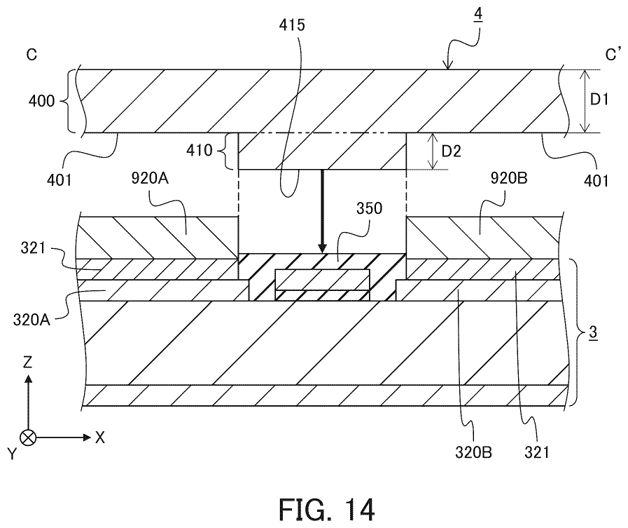

FIG. 14 is a cross-sectional view illustrating a configuration example of a metal wiring board in a semiconductor device according to a fourth embodiment. The cross section illustrated in FIG. 14 corresponds to a cross section (that is, a cross section at a position of a line with alternating long and short dashes C-C′ in FIG. 9A) illustrated in FIG. 9B.

In the present embodiment, variations of a method of forming a separation portion 410 in a first bonding portion 400 of a metal wiring board 4 will be described. In order to simplify the description, main electrodes (emitter electrodes) on an upper surface of a semiconductor element 3 bonded to the metal wiring board 4 are assumed to be the first pad 320A and the second pad 320B exemplified in the first embodiment (see FIG. 6A). In the first embodiment, a method of forming the separation portion 410 by press working has been described as an example of the method of forming the separation portion (see FIG. 8). In a case where the separation portion 410 is formed in the first bonding portion 400 of the metal wiring board 4 by the method described in the first embodiment, a recess corresponding to the separation portion 410 is formed on an upper surface of the first bonding portion 400. However, the method of forming the separation portion 410 is not limited to such a method of forming the recess on the upper surface of the first bonding portion 400. As illustrated in FIG. 14, the method of forming the separation portion 410 may be a method in which a region corresponding to the separation portion 410 on the upper surface of the first bonding portion 400 is a flat surface. From another point of view, the method of forming the separation portion 410 may be a method of forming the first bonding portion 400 such that a thickness of a portion where the separation portion 410 is formed is larger than thicknesses of portions facing main electrodes 320A and 320B of the semiconductor element 3. The separation portion 410 of the metal wiring board 4 illustrated in FIG. 14 can be a portion protruding downward (toward the negative side in the Z direction) from a line with alternating long and two short dashes continuous with a lower surface 401 of the first bonding portion 400. The first bonding portion 400 having such a separation portion 410 is formed by, for example, thinning a region outside a region to be the separation portion 410 in the first bonding portion 400 in the metal wiring board 4 in which the entire first bonding portion 400 has the thickness (D1+D2) of the portion where the separation portion 410 is formed. The separation portion 410 of the metal wiring board 4 according to the present embodiment can be formed by, for example, etching, milling (cutting), or the like with a lower surface side of the first bonding portion 400 as a processing target. In addition, the separation portion 410 of the metal wiring board 4 according to the present embodiment may be formed by, for example, pressing the first bonding portion 400 having a single thickness with a lower die having the recess corresponding to a shape of the separation portion 410 disposed on the lower surface side of the first bonding portion 400 and a flat upper die disposed on an upper surface side of the first bonding portion 400 to thin the region outside the region to be the separation portion 410.

In a case where the separation portion 410 is formed in the first bonding portion 400 of the metal wiring board 4 by the method described in the first embodiment, the recess corresponding to the separation portion 410 is formed on the upper surface of the first bonding portion 400 as described above. The formation of the recess can result in a portion thinner than a region to be bonded, at a boundary portion between the region to be bonded by bonding materials 920A and 920B and the separation portion 410 in the first bonding portion 400 (see FIG. 9B). Therefore, the first bonding portion 400 is easily deformed at the portion thinner than the region to be bonded. The deformation of the first bonding portion 400 may cause variations in a distance from an upper surface of the main electrode (plating layer 321) of the semiconductor element 3 to the lower surface 401 of the first bonding portion 400. For this reason, for example, variations of a bonding strength for each semiconductor device 1 increases due to the variations of thicknesses of the bonding materials 920A and 920B for each semiconductor device 1, and thus, a probability of occurrence of a product defect may increase. On the other hand, in the metal wiring board 4 of the present embodiment, the portion thinner than the region to be bonded is not formed at the boundary portion between the region to be bonded by the bonding materials 920A and 920B in the first bonding portion 400 and the separation portion 410. Therefore, in the metal wiring board 4 of the present embodiment, the first bonding portion 400 is hardly deformed, and it is possible to prevent the probability of occurrence of a product defect from being increased due to the variations of the thicknesses of the bonding materials 920A and 920B.

A plane shape of the separation portion 410 in the metal wiring board 4 according to the present embodiment is not limited to a specific shape. The plane shape of the separation portion 410 may be any shape as long as a distal end surface 415 is in contact with an insulating layer 350 of the semiconductor element 3 and no bridge of the bonding material is formed, or the formation of the bridge of the bonding material can be suppressed. The separation portion 410 may be formed such that the plane shape is a single rectangle (oblong) as illustrated in FIG. 12B. The separation portion 410 may be formed to have a cross plane shape as illustrated in FIG. 13.

### Fifth Embodiment

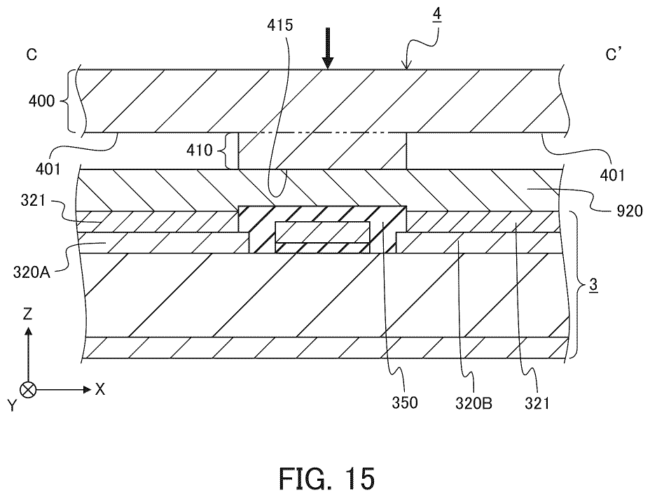

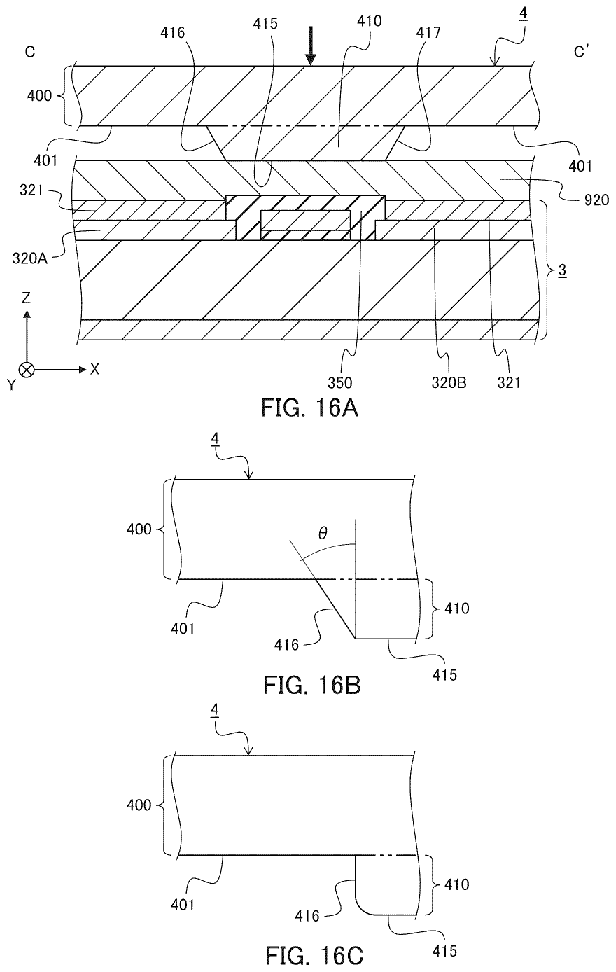

FIG. 15 is a cross-sectional view for describing an example of a bonding procedure between a main electrode of a semiconductor element and a metal wiring board according to a fifth embodiment. FIGS. 16A to 16C are cross-sectional views illustrating other configuration examples of the metal wiring board according to the fifth embodiment.

In the present embodiment, variations of a method of bonding main electrodes 320 on an upper surface of a semiconductor element 3 and a first bonding portion 400 of a metal wiring board 4 will be described. In the above-described embodiment, plate solders are separately disposed on the main electrodes (a first pad 320A and a second pad 320B) provided on the upper surface of semiconductor element 3, respectively, and the metal wiring board 4 is disposed such that a separation portion 410 formed in the first bonding portion 400 of the metal wiring board 4 is fitted between the adjacent plate solders. However, the method of bonding the main electrodes 320A and 320B on the upper surface of the semiconductor element 3 and the first bonding portion 400 of the metal wiring board 4 is not limited to such a method. For example, as illustrated in FIG. 15, a bonding material disposed on the upper surface of the semiconductor element 3 may be one plate solder (bonding material 920) including a portion disposed on the first pad 320A and a portion disposed on the second pad 320B. In a case where one plate solder is disposed between the semiconductor element 3 and the metal wiring board 4, after the metal wiring board 4 is disposed on the plate solder, for example, the bonding material is melted in a state in which a pressing load for pressing the first bonding portion 400 from an upper surface of the first bonding portion 400 of the metal wiring board 4 toward the semiconductor element 3 is applied. When the bonding material is melted, the separation portion 410 of the first bonding portion 400 enters the melted bonding material layer by the pressing load applied to the first bonding portion 400, and pushes out the melted bonding material on an insulating layer 350 onto the first pad 320A and the second pad 320B. Therefore, it is possible to prevent contact between a distal end surface 415 of the separation portion 410 of the first bonding portion 400 and the insulating layer 350 of the semiconductor element 3, formation of a bridge of the bonding material on the insulating layer 350, and generation of a closed gap.

In the separation portion 410 of the metal wiring board 4 according to the present embodiment, as illustrated in FIG. 16A, a side surface 416 along a boundary with a region facing the first pad 320A and a side surface 417 along a boundary with a region facing the second pad 320B on a lower surface of the first bonding portion 400 may be tapered toward the distal end surface 415. By tapering the side surfaces 416 and 417 of the separation portion 410, the separation portion 410 can be smoothly pushed into the layer of the melted bonding material 920, and the melted bonding material 920 on the insulating layer 350 can be pushed out onto the first pad 320A and the second pad 320B. In a case where the side surfaces 416 and 417 of the separation portion 410 are tapered, a gradient θ of the side surface 416 illustrated in FIG. 16B (and the side surface 417 (not illustrated)) is not limited to a specific value. In addition, instead of tapering the side surfaces 416 and 417, the separation portion 410 may have a chamfered corner portion where the distal end surface 415 and the side surface 416 are in contact with each other and a chamfered corner portion where the distal end surface 415 and the side surface 417 (not illustrated) are in contact with each other as illustrated in FIG. 16C.

### Sixth Embodiment

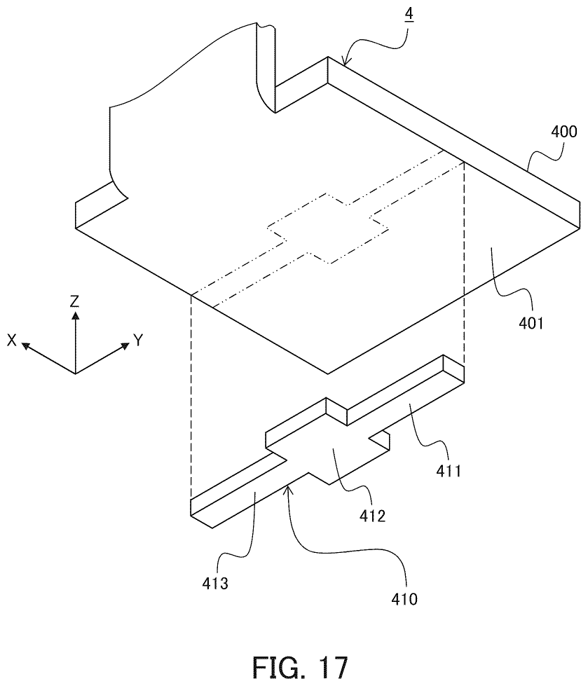

FIG. 17 is an exploded perspective view illustrating a method of forming a separation portion of a metal wiring board according to a sixth embodiment.

In the present embodiment, still another method of forming a separation portion 410 of a metal wiring board 4 will be described. The separation portion 410 of the metal wiring board 4 in the above-described embodiment is formed by performing pressing, etching, cutting, or the like on the flat-plate-shaped first bonding portion 400 having a uniform thickness. However, the method of forming the separation portion 410 is not limited to such a method. For example, as illustrated in FIG. 17, the separation portion 410 may be formed separately from the metal wiring board 4 including a flat-plate-shaped first bonding portion 400 having a uniform thickness, and may be attached to a lower surface 401 of the first bonding portion 400. The separation portion 410 can be formed by a known method such as punching. The separation portion 410 is attached to the lower surface 401 of the first bonding portion 400 using, for example, a bonding material, a brazing material, or the like. The separation portion 410 may be attached to the lower surface 401 of the first bonding portion 400 by, for example, ultrasonic bonding.

In a case where the separation portion 410 is formed separately from the metal wiring board 4, for example, after a plate solder and the separation portion 410 are disposed on an upper surface of a semiconductor element 3, the flat-plate-shaped metal wiring board 4 may be disposed such that the first bonding portion 400 is disposed on the separation portion 410, and the plate solder may be melted. As in the present embodiment, the separation portion 410 may be formed as a component separate from the metal wiring board 4, and may be disposed between an insulating layer 350 of the semiconductor element 3 and the metal wiring board 4. In this example, a bridge can be prevented from being formed on the insulating layer 350 by forming the separation portion 410 into a shape having a flat surface that is in contact with the insulating layer 350 and a flat surface that is in contact with the lower surface of the first bonding portion 400 of the metal wiring board 4.

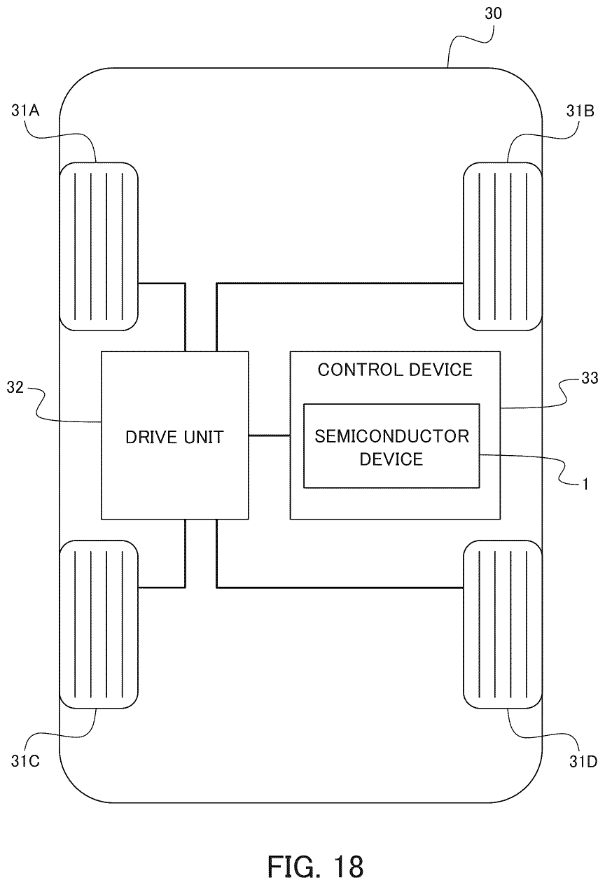

The semiconductor devices 1 of the above-described embodiments are not limited to a specific application, but are particularly suitable for an application requiring a large current. For example, the semiconductor devices 1 of the above-described embodiments can be applied to a power conversion device such as an inverter device that drives a motor mounted on a vehicle. A vehicle to which the semiconductor device 1 according to the present invention is applied is described with reference to FIG. 18.

FIG. 18 is a schematic plan view illustrating an example of the vehicle to which the semiconductor device according to the present invention is applied. A vehicle 30 illustrated in FIG. 18 can be, for example, a four-wheeled vehicle including four wheels 31A to 31D. The vehicle 30 may be, for example, an electric vehicle that drives the wheels by a motor, or a hybrid vehicle using power of an internal combustion engine in addition to the motor. In addition, the vehicle to which the semiconductor device 1 is applied is not limited to a four-wheeled vehicle, and may be, for example, a two-wheeled vehicle or a railway vehicle.

The vehicle 30 includes a drive unit 32 that applies power to the wheels 31A to 31D, and a control device 33 that controls the drive unit 32. The drive unit 32 may include, for example, at least one of a motor or a hybrid system combining an engine and a motor. The drive unit 32 in the four-wheeled vehicle is not limited to one that applies power to all of the four wheels 31A to 31D illustrated in FIG. 18. The drive unit 32 may apply power to two wheels referred to as front wheels among the four wheels 31A to 31D or two wheels referred to as rear wheels.

The control device 33 performs control (for example, electric power control) on the drive unit 32. The control device 33 includes the semiconductor device 1 of the above-described embodiment. The semiconductor device 1 may be configured to perform the electric power control on the drive unit 32. Although only one semiconductor device 1 is illustrated in FIG. 18, in the actual vehicle 30, a plurality of semiconductor devices 1 may be used to form an inverter circuit such as the half-bridge inverter circuit 20 described above with reference to FIG. 4. The vehicle 30 may include the semiconductor device 1 of the above-described embodiment as a semiconductor device that performs electric power control (for example, control of electric power supplied to various electrical components) different from the electric power control for the drive unit 32.

The semiconductor devices 1 of the above-described embodiments are not limited to application to an inverter device for a vehicle, and are applicable to, for example, an inverter device such as an elevator, an air conditioning system, or an industrial pump.

The embodiment of the semiconductor device 1 according to the present invention is not limited to the above-described embodiment, and various changes, substitutions, and modifications may be made without departing from the spirit of the technical idea. Further, when the technical idea can be implemented in another manner by the progress of the technology or another derived technology, the technical idea may be carried out by using a method thereof. Therefore, the claims cover all embodiments that may be included within the scope of the technical idea.

Hereinafter, feature points in the above-described embodiments are summarized.

The semiconductor device according to the above-described embodiment includes: a semiconductor element in which a plurality of metal layers adjacent to each other with an insulating layer interposed therebetween are exposed on a first surface; a metal wiring board that is bonded to the plurality of metal layers of the semiconductor element via bonding materials; and a separation portion that is provided between the semiconductor element and the metal wiring board, has a region overlapping with the insulating layer in plan view of the first surface, and separates a plurality of regions respectively overlapping with the plurality of metal layers in the metal wiring board.

In the semiconductor device according to the above-described embodiment, the separation portion is a part of the metal wiring board.

In the semiconductor device according to the above-described embodiment, the separation portion has a flat surface at a distal end portion, and the flat surface of the distal end portion is in contact with the insulating layer of the semiconductor element.

In the semiconductor device according to the above-described embodiment, in the separation portion, a dimension of the region in a first direction is the same as a dimension of the insulating layer in the first direction, the region overlapping with the insulating layer between metal layers adjacent in the first direction on the first surface of the semiconductor element.

In the semiconductor device according to the above-described embodiment, the plurality of metal layers of the semiconductor element are one of a pair of main electrodes of a switching element.

In the semiconductor device according to the above-described embodiment, a control electrode of the switching element is further exposed on the first surface of the semiconductor element, and the insulating layer covers a runner portion connected to the control electrode and extending between adjacent metal layers on the first surface.

In the semiconductor device according to the above-described embodiment, the insulating layer has a section whose dimension in a direction orthogonal to an extending direction is a first width in plan view of the first surface, and a wide section whose dimension is larger than the first width.

In the semiconductor device according to the above-described embodiment, the separation portion is separate from the metal wiring board and has a flat surface that is in contact with the insulating layer of the semiconductor element and a flat surface that is in contact with the metal wiring board.

The semiconductor device according to the above-described embodiment further includes an insulating member that seals the semiconductor element and the metal wiring board.

The semiconductor device according to the above-described embodiment further includes a cooler thermally connected to the semiconductor element.

The vehicle according to the above-described embodiment includes the semiconductor device according to the above-described embodiment.

### INDUSTRIAL APPLICABILITY

As described above, the present invention can prevent occurrence of a product defect due to scattering of a bonding material used for bonding a main electrode of a semiconductor element and a metal wiring board, and is particularly useful for application to an industrial or vehicular power conversion device that requires a large current.

What is claimed is:

1. A semiconductor device comprising:
a semiconductor element including, formed at a first surface thereof:
a pair of metal layers adjacent to each other, and
an insulating layer interposed between the pair of metal layers;
a metal wiring board that is bonded to the pair of metal layers of the semiconductor element respectively via a pair of bonding materials, the metal wiring board including a pair of regions thereof respectively overlapping with the pair of metal layers in a plan view of the semiconductor device; and
a separation portion provided between the semiconductor element and the metal wiring board, and separating the pair of regions of the metal wiring board.

2. The semiconductor device according to claim 1, wherein the separation portion is formed integrally with the metal wiring board.

3. The semiconductor device according to claim 2, wherein the separation portion has a flat surface at a distal end portion thereof, the flat surface being in contact with the insulating layer of the semiconductor element.

4. The semiconductor device according to claim 1, wherein
the separation portion includes a region overlapping with the insulating layer in the plan view,
a width of the region in a first direction is the same as a width of the insulating layer in the first direction, and
the region is formed between the pair of metal layers adjacent in the first direction.

5. The semiconductor device according to claim 1, wherein
the semiconductor element includes a switching element, and
the pair of metal layers forms a pair of main electrodes of the switching element.

6. The semiconductor device according to claim 5, wherein
the switching element further includes a control electrode that is exposed on the first surface thereof,
the semiconductor device further includes a runner portion connected to the control electrode and extending between the pair of metal layers on the first surface, and
the insulating layer covers the runner portion.

7. The semiconductor device according to claim 1, wherein the insulating layer has a first section and a second section in an extending direction in which the insulating layer extends, the second section being wider than the first section in a width direction orthogonal to the extending direction.

8. The semiconductor device according to claim 1, wherein the separation portion is separate from the metal wiring board, and has a first flat surface that is in contact with the insulating layer of the semiconductor element and a second flat surface that is in contact with the metal wiring board.

9. The semiconductor device according to claim 1, further comprising an insulating member that seals the semiconductor element and the metal wiring board.

10. The semiconductor device according to claim 1, further comprising a cooler thermally connected to the semiconductor element.

11. A vehicle, comprising the semiconductor device according to claim 10.

12. A vehicle, comprising the semiconductor device according to claim 9.

13. A vehicle, comprising the semiconductor device according to claim 8.

14. A vehicle, comprising the semiconductor device according to claim 7.

15. A vehicle, comprising the semiconductor device according to claim 6.

16. A vehicle, comprising the semiconductor device according to claim 5.

17. A vehicle, comprising the semiconductor device according to claim 4.

18. A vehicle, comprising the semiconductor device according to claim 3.

19. A vehicle, comprising the semiconductor device according to claim 2.

20. A vehicle, comprising the semiconductor device according to claim 1.
